(19) United States
(12) Patent Application Publication
(10) Pub. No.: US 2021/0333968 A1
(43) Pub. Date: Oct. 28, 2021

(54) ARRAY SUBSTRATE AND MANUFACTURING METHOD THEREOF, AND DISPLAY DEVICE

(71) Applicants: ORDOS YUANSHENG OPTOELECTRONICS CO., LTD., Ordos, Inner Mongolia (CN); BOE TECHNOLOGY GROUP CO., LTD., Beijing (CN)

(72) Inventors: Xinguo WU, Beijing (CN); Fengguo WANG, Beijing (CN); Dawei SHI, Beijing (CN); Hong LIU, Beijing (CN); Zifeng WANG, Beijing (CN); Feng LI, Beijing (CN); Bo MA, Beijing (CN); Zhixuan GUO, Beijing (CN); Yuanbo LI, Beijing (CN); Cenhong DUAN, Beijing (CN); Jing ZHAO, Beijing (CN)

(73) Assignees: ORDOS YUANSHENG OPTOELECTRONICS CO., LTD., Ordos, Inner Mongolia (CN); BOE TECHNOLOGY GROUP CO., LTD., Beijing (CN)

(21) Appl. No.: 16/473,718

(22) PCT Filed: Nov. 30, 2018
(86) PCT No.: PCT/CN2018/118516

§ 371 Date: Jun. 26, 2019

(30) Foreign Application Priority Data
Mar. 27, 2018 (CN) 201810258988.X

(51) Int. Cl. G06F 3/041

(52) U.S. Cl. CPC G06F 3/04164; G06F 2203/04103

(57) ABSTRACT

The present disclosure provides an array substrate and a manufacturing method thereof, and a display device. The array substrate includes a display area and a peripheral circuit area. The array substrate further includes a plurality of touch electrodes located in the display area; a plurality of touch signal lines connecting the plurality of touch electrodes to the peripheral circuit area; a plurality of first conductor lines extending in a same direction as the plurality of touch signal lines; and a plurality of second conductor lines extending in a different direction from the plurality of touch signal lines.

### CROSS-REFERENCE TO RELATED APPLICATION

The present application claims the priority of Chinese Patent Application No. 201810258988.X filed on Mar. 27, 2018, the contents of which are incorporated herein in their entirety by reference.

### TECHNICAL FIELD

The present disclosure relates to the field of display technology, in particular to an array substrate and a manufacturing method thereof, and a display device.

### BACKGROUND

In a touch product such as a touch and display driver integration (TDDI), a poor touch event is likely to occur due to an excessive resistance of a transparent touch electrode and a low signal strength of the received touch signal.

### SUMMARY

An array substrate includes a display area and a peripheral circuit area, and the array substrate further includes:

a plurality of touch electrodes located in the display area;

a plurality of touch signal lines connecting the plurality of touch electrodes to the peripheral circuit area;

a plurality of first conductor lines extending in a same direction as the plurality of touch signal lines; and

a plurality of second conductor lines extending in a different direction from the plurality of touch signal lines;

wherein each touch electrode is connected to at least one first conductor line in a thickness direction of the touch electrode, and is connected to at least one touch signal line, the at least one touch signal line is connected to at least one second conductor line, and the at least one second conductor line is connected to the at least one first conductor line.

In some embodiments, each one of the touch electrodes is connected to the peripheral circuit area by the at least one touch signal line;

the plurality of touch signal lines are formed in a same patterning process as the plurality of first conductor lines; and

the plurality of first conductor lines comprise at least one invalid touch signal line, wherein each one of the at least one invalid touch signal line is a conductor line other than the plurality of touch signal lines that is on a same straight line as any touch signal line.

In some embodiments, the array substrate includes a plurality of rows of gate lines and a plurality of columns of data lines, wherein the plurality of second conductor lines are formed in a same patterning process as the plurality of rows of gate lines, and the plurality of first conductor lines, the plurality of touch signal lines and the plurality of columns of data lines are formed in a same patterning process.

In some embodiments, the array substrate includes an insulation layer, wherein the plurality of rows of gate lines and the plurality of columns of data lines are located on either side of the insulation layer in a thickness direction thereof, respectively, a first via is provided in the insulation layer, and each second conductor line is connected to a corresponding first conductor line and a corresponding touch signal line through the first via.

In some embodiments, the array substrate includes an insulation layer, wherein the plurality of touch signal lines and the plurality of touch electrodes are located on either side of the insulation layer in a thickness direction thereof, respectively;

a plurality of vias are provided in the insulation layer, each touch signal line is connected to a corresponding touch electrode through at least one via, each first conductor line is connected to a corresponding touch electrode through at least one via; and

the plurality of touch signal lines and the plurality of first conductor lines are formed in a same patterning process.

In some embodiments, the plurality of touch signal lines, the plurality of first conductor lines and the plurality of second conductor lines are formed in a same patterning process.

In some embodiments, the display area includes a plurality of rows and columns of pixel aperture regions, each touch signal line is located between two adjacent columns of pixel aperture regions, each first conductor line is located between two adjacent columns of pixel aperture regions, and each second conductor line is located between two adjacent rows of pixel aperture regions.

In some embodiments, all the first conductor lines connected to one touch electrode are located within a region where the touch electrode is located; and

the second conductor lines connected to the first conductor lines which are all connected to the touch electrode are located within the region where the touch electrode is located.

In some embodiments, only one second conductor line is connected to the first conductor lines which are all connected to one touch electrode, and the second conductor line is located at a center of a region where the touch electrode is located;

or,

two second conductor lines are connected to the first conductor lines which are all connected to one touch electrode, and one of the two second conductor lines is located at a first edge of the region where the touch electrode is located, and the other is located at a second edge of the region where the touch electrode is located.

A display device includes the array substrate according to any of the above.

A manufacturing method of an array substrate includes:

forming a plurality of touch signal lines, wherein the plurality of touch signal lines have a same extending direction;

forming a plurality of first conductor lines, wherein the plurality of first conductor lines extend in a same direction as the plurality of touch signal lines;

forming a plurality of second conductor lines, wherein the plurality of second conductor lines extend in a different direction from the plurality of touch signal lines; and

forming a plurality of touch electrodes, wherein the array substrate includes a display area and a peripheral circuit area, the plurality of touch electrodes are located within the display area, and the plurality of touch electrodes are connected to the peripheral circuit area through the plurality of touch signal lines;

wherein each touch electrode is connected to at least one first conductor line in a thickness direction of the touch electrode, and is connected to at least one touch signal line, the at least one touch signal line is connected to at least one second conductor line, and the at least one second conductor line is connected to the at least one first conductor line.

### BRIEF DESCRIPTION OF THE DRAWINGS

FIG. 1 is a structural diagram of an array substrate provided by some embodiments;

FIG. 2 is a schematic diagram of layout of a display area of an array substrate provided by some embodiments;

FIG. 3 is a schematic sectional view of an array substrate provided by some embodiments at a first via;

FIG. 4 is a schematic sectional view of an array substrate provided by some embodiments at a second via;

FIG. 5A is a schematic diagram of touch wirings of an array substrate provided by some embodiments;

FIG. 5B is a schematic diagram of touch wirings of an array substrate provided by some other embodiments;

FIG. 6 is a schematic diagram of touch wirings of an array substrate provided by some other embodiments;

FIG. 7 is a schematic diagram of touch wirings of an array substrate provided by some other embodiments;

FIG. 8 is a schematic diagram of touch wirings of an array substrate provided by some other embodiments;

FIG. 9 is a schematic diagram of touch wirings of an array substrate provided by some other embodiments;

FIG. 10 is a schematic flow chart of a manufacturing method of an array substrate provided by some embodiments; and

FIG. 11 is a structural diagram of a display device provided by some embodiments.

### DETAILED DESCRIPTION

Unless otherwise defined, technical terms or scientific terms used in the present disclosure are intended to be understood in the ordinary sense of the ordinary skill of the art to which the present disclosure belongs. The words “first”, “second”, and similar words used in the present disclosure do not denote any order, quantity, or importance, but are used to distinguish different components. “Comprising” or a similar word means that the element or item that appears before the word includes the element or item and their equivalent that appears after the word, and do not exclude other elements or items. The word “connection” or “connecting” and the like appearing alone is not limited to a physical or mechanical connection. In some embodiments, the connection refers to an electrical connection. In some embodiments, the connection is a direct or an indirect connection.

In a touch product using the TDDI, a poor touch event is likely to occur due to an excessive resistance of a transparent touch electrode and a low signal strength of the received touch signal. In the touch product using the TDDI, for example, in a display area covering 5 mm×5 mm, the touch electrodes generally transmit the collected touch signals to an external chip through metal leads. Since the number of metal leads is limited by the aperture ratio, the metal leads cannot be arranged densely; meanwhile, the touch signals generated on the touch electrodes at a position farther away from the metal leads have a considerable signal attenuation during the transmission process; therefore, local touch signals are easily covered by noise, resulting in poor touch events.

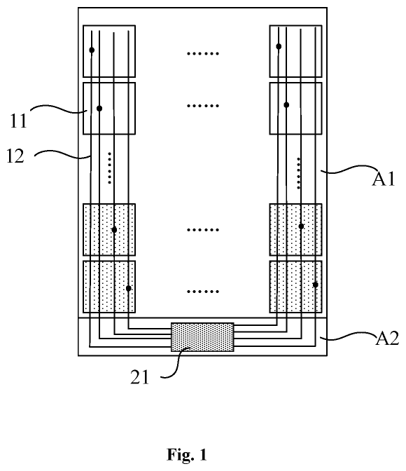

FIG. 1 is a structural diagram of an array substrate provided by some embodiments. Referring to FIG. 1, the array substrate includes a display area A1 and a peripheral circuit area A2. The substrate further includes a plurality of touch electrodes 1 located in the display area A1. As exemplified in FIG. 1, the peripheral circuit area A2 is located on a side of the display area A1, and the plurality of touch electrodes 11 are arranged in multiple rows and columns in the display area A1.

In some embodiments, the peripheral circuit area A2 is located on two opposite sides of the display area A1.

In some embodiments, the peripheral circuit area A2 surrounds the display area A1.

In some embodiments, the plurality of touch electrodes 11 is arranged in any unit arrangement manner in a plane. For example, the plurality of touch electrodes 11 is arranged in an inclined grid, a triangular grid, or a diamond-shaped grid.

As an example, FIG. 1 further shows a touch circuit 21 located in the peripheral circuit area A2. The touch circuit 21 is configured to achieve the touch sensing by collecting the electrical signals on the plurality of touch electrodes 11.

In some embodiments, the touch circuit 21 is electrically connected to the plurality of touch electrodes 11. That is, the plurality of touch electrodes 11 are connected to the peripheral circuit area A2 by a plurality of touch signal lines 12.

In some embodiments, as shown in FIG. 1, the touch circuit 21 is located on a side of the display area A1. The above a plurality of touch signal lines 12 all extend in a direction from the display area A1 to the peripheral circuit area A2.

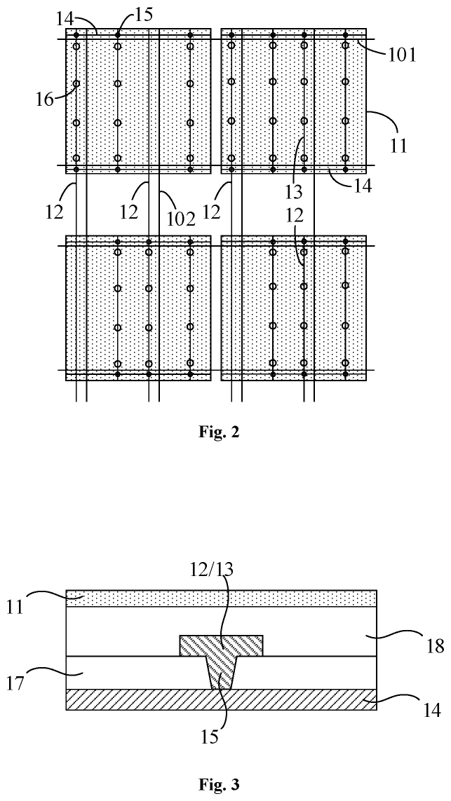

FIG. 2 is a schematic diagram of layout of the display area of an array substrate provided by some embodiments. FIG. 2 exemplarily shows 4 touch electrodes 11 arranged in two rows and two columns. As shown in FIG. 2, the array substrate includes the above a plurality of touch electrodes 11, the plurality of touch signal lines 12, a plurality of first conductor lines 13, a plurality of second conductor lines 14, a plurality of rows of gate lines 101 and a plurality of columns of data lines 102. As shown in FIG. 2, the plurality of touch signal lines 12 in the array substrate have a same extending direction, each first conductor line 13 extends in the same direction as the plurality of touch signal lines 12, and each second conductor line 14 extends in a different direction as the plurality of touch signal lines 12.

As for connection relationships, each first conductor line 13 is connected to one touch electrode 11 in a thickness direction of this touch electrode 11, each second electrode line 13 corresponds to one touch electrode 11, any second conductor line 14 is connected to a touch signal line 12 connected to the corresponding touch electrode 11, and any second conductor line 14 is connected to each of the first conductor lines 13 connected to the corresponding touch electrode 11, respectively.

As shown in FIG. 2, any touch electrode 11 is connected to a plurality of first conductor lines 13 in the thickness direction thereof, and is connected to one touch signal line 12 which is connected to a plurality of second conductor lines 14. Each of the second conductor lines 4 connected to this touch signal line 12 is connected to the plurality of first conductor lines 13 which are connected to this touch electrode 11.

As shown in FIG. 2, the plurality of first conductor lines 13 connected to any touch electrode 11 are located in the region of the touch electrode 11; the touch electrode 11 is connected to one touch signal line 12, and the plurality of second conductor lines 14 connected to the touch signal line 12 are located in the region of the touch electrode 11.

In the above embodiment, based on the arrangement of the first conductor lines 13 and the second conductor lines 14, the touch signals on the touch electrodes 11 can not only be directly transmitted to the touch signal lines 12, but also transmitted to the touch signal lines 12 via the first conductor lines 13 and the second conductor lines 14; moreover, the resistances between a plurality of positions on the touch electrodes 11 and the touch signal lines 12 are also uniformed. That is, the above embodiment of the present disclosure increases the number of the contact points between the touch signal lines and the touch electrodes, and reduces the resistance from the edge of a touch electrode to a touch signal line, thereby improving the signal intensity of the touch signals received by the touch electrodes, reducing poor touch events, and improving the touch performance of a product.

For example, the plurality of second conductor lines 14 are formed in a same patterning process as the plurality of gate lines 101; the plurality of first conductor lines 13, the plurality of touch signal lines 12 and the plurality of columns of date lines 102 are formed in a same patterning process. In this way, the second conductor lines 14 and the gate lines 101 are located in a same layer, and the first conductor lines 13, the touch signal lines 12 and the date lines 102 are located in a same layer.

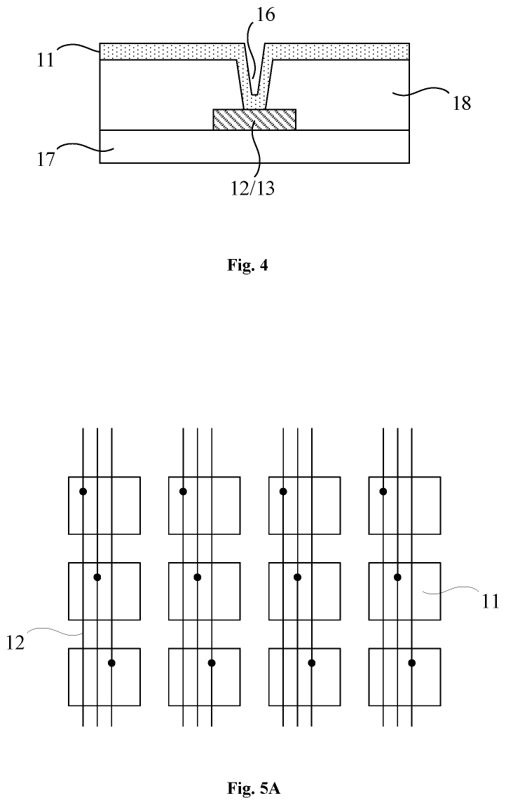

For example, as shown in FIGS. 3 and 4, the array substrate further includes a first insulation layer 17; the plurality of rows of gate lines 101 (in the same layer as the second conductor lines 14) and the plurality of columns of data lines 102 (in the same layer as the first conductor lines 13 and the touch signal lines 12) are located on either side of the first insulation layer 17 in the thickness direction of the first insulation layer 17.

Taking a bottom-gate type structure in which the first insulation layer includes a gate insulation layer as an example, the second conductor lines 14 and the gate lines GL are located on a first side of the first insulation layer, while the first conductor lines 13, the touch signal lines 12 and the date lines 102 are located on a second side of the first insulation layer.

FIG. 3 is a schematic sectional view of an array substrate provided by some embodiments at a first via. Also referring to FIG. 2, FIG. 3 shows the sectional view at the position indicated by the symbol “15” in FIG. 2. Exemplarily, referring to FIG. 3, the array substrate includes the first insulation layer in which a first via 15 is provided, and any second conductor line 14 is connected to a corresponding first conductor line 13 and a corresponding touch signal line 12 through the first via 15. In this way, the above touch signal line 12 and the above second conductor line 14 are connected with each other through the first via 15 at a position on the touch electrode 11 at which the projections of the touch signal line 12 and the second conductor line 14 intersect, and the above first conductor line 13 and the above second conductor line 14 are connected with each other through the first via 15 at a position on the touch electrode 11 at which the projections of the first conductor line 13 and the second conductor line 14 intersect.

Exemplarily, the array substrate further includes a second insulation layer, and the plurality of touch signal lines 12 and the plurality of touch electrodes 11 are located on either side of the second insulation layer in the thickness direction of the second insulation layer.

Thus, taking that the touch electrodes 11 are located on a side of the second insulation layer far from the first insulation layer as an example, the first conductor lines 13, the touch signal lines 12 and the date lines 102 are located on a first side of the second insulation layer, and the touch electrodes 11 are located on a second side of the second insulation layer.

In some embodiments, the touch electrodes 11 in the above example are common electrodes for providing a common voltage.

FIG. 4 is a schematic sectional view of an array substrate provided by some embodiments at a second via. FIG. 4 shows the sectional view at a position indicated by the symbol “16” in FIG. 2. Exemplarily, the array substrate includes a second insulation layer 18 in which a plurality of vias 16 are provided. Any touch signal line 12 is connected to a corresponding touch electrode 11 through at least one second via 16, and each first conductor line 13 is connected a corresponding touch electrode 11 through at least one second via 16.

Thus, the above connection between the touch signal line 12 and the touch electrode 11, and the above connection between the first conductor line 13 and the touch electrode 11 are achieved through at least one second via 16.

The second conductor lines 14 are located on the first side of the first insulation layer 17, while the first conductor lines 13 and the touch signal lines 12 are located on the second side of the first insulation layer 17. The first via 15 is provided in the first insulation layer 17, and a second conductor line 14 is connected to a corresponding first conductor line 13 through the first via 15. The first conductor lines 13 and the touch signal lines 12 are located on the first side of the second insulation layer 18, while the touch electrodes 11 are located on the second side of the second insulation layer 18. A plurality of second vias 16 are provided in the second insulation layer 18, and a touch signal line 12 is connected to a corresponding touch electrode 11 through the second vias 16.

In FIG. 2, in the order from left to right, the four touch signal lines 12 are connected to the upper left, lower left, upper right, and lower right touch electrodes 11, respectively. The touch electrodes 11 are connected to corresponding touch signals 12 through the second vias 16.

Taking FIG. 2 as an example, in the array substrate, each touch signal line 12 connects one touch electrode 11 to the peripheral circuit area, which makes the plurality of touch electrodes 11 be electrically insulated from each other while satisfying the requirement of collecting the touch signals, thereby avoiding the interference between the touch signals on different touch electrodes 11.

In some embodiments, referring to FIGS. 1 and 2, in order that the touch signal on each touch electrode 11 can be transmitted to the peripheral circuit area A2 separately, the range of projection in the row direction of each column of touch electrodes 11 allows at least the same number of touch signal lines 12 as the number of rows of the touch electrodes to be arranged in parallel in the column direction in the range of projection. That is, the size of a touch electrode 11, the line width of a touch signal line 12, and the arrangement pitch of the touch signal lines 12 all meet corresponding restrictions.

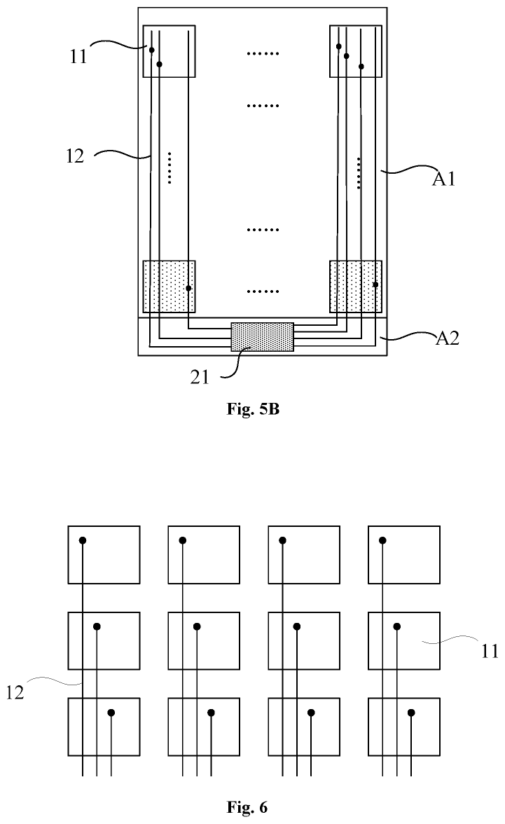

For example, FIG. 5A shows touch electrodes 11 arranged in 3 rows and 4 columns. Since each touch signal line 12 transmits into the peripheral circuit area A2 the touch signal on the touch electrode 11 connected thereto along the column direction, the range of projection in the row direction of each column of touch electrodes 11 allows at least 3 touch signal lines 12 to be arranged in parallel in the column direction in the range of projection. In the present example, the number of the touch signal lines in the range of projection of each column of touch electrodes 11 is not less than the total number of rows of the touch electrodes 11.

In some embodiments, in a case that the number of the touch signal lines in the range of projection of each column of touch electrodes 11 is greater than the total number of rows of the touch electrodes 11, some touch electrodes are connected to two or more touch signal lines 12.

In some embodiments, as shown in FIG. 5B, some touch electrodes are connected to two touch signal lines 12, and some others are connected to three touch signal lines 12.

In an example, a touch electrode 11 far from the touch circuit 21 is configured to be connected to more than one touch signal line 12 so as to compensate the resistor voltage drop of the touch signal on a distal touch electrode 11 far from the touch circuit 21. For example, a touch electrode 11 farthest from the touch circuit 21 is connected to at least two touch signal lines 12, and a touch electrode 11 closest to the touch electrode 11 is connected to one touch signal line 12.

In some embodiments, as shown in FIG. 6, the wiring of the arrays substrate is simplified on the basis of the structure shown in FIG. 5A. Comparing FIG. 6 with FIG. 5A, it can be seen that, in the array substrate with the simplified wiring, the lines corresponding to the transmission paths of the touch signals are retained, while the lines in the touch signal lines 12 that do not serve to transmit the touch signals are removed. Since this change is achieved only by modifying the mask pattern corresponding to the conductor film layer where the touch signal lines are located, it does not have a large influence on the original manufacturing process. In this way, the wiring space of the redundant lines is advantageously omitted, and the redundant lines are prevented from causing short circuits or crosstalk.

In some embodiments, FIG. 7 shows a structure of an array substrate provided by some embodiments which is simplified on the basis of the structure shown in FIG. 5A. Comparing FIG. 7 with FIG. 6, it can be seen that, some lines in the touch signal lines 12 which do not serve to transmit signals are not completely removed, but a part of these lines which are located between two adjacent rows of touch electrodes 11 (which is also achieved by changing the mask pattern corresponding to the conductor film layer where the touch signal lines are located), thereby forming, by using the manufacturing process of the touch signal lines 12 advantageously, the above first conductor lines 13 which helps to conduct the touch signals from the touch electrodes to the touch signal lines 12.

Without any other connection arrangement, a first conductor line 13 directly separated from a touch signal line 12 is a conductor line which does not have any useful function (the “useful function” here refers to a signal transmission function). For convenience of description, a conductor line that is separated from at least one of the above touch signal lines and that is on the same straight line as any of the touch signal lines is referred to as an invalid touch signal line. The first conductor lines 13 are not necessarily all invalid touch signal lines (for example, the rightmost first conductor line 13 in the range of orthographic projection of each touch electrode 11 in FIG. 7 is not an invalid touch signal line).

In some embodiments, for different touch electrodes 11, the numbers of the invalid touch signal lines in the regions where these touch electrodes 11 are located are different (as shown in FIG. 7). The first conductor line 13 indicated by the symbol “13” in the region where the upper right touch electrode 11 is located as shown in FIG. 2 is an invalid touch signal line.

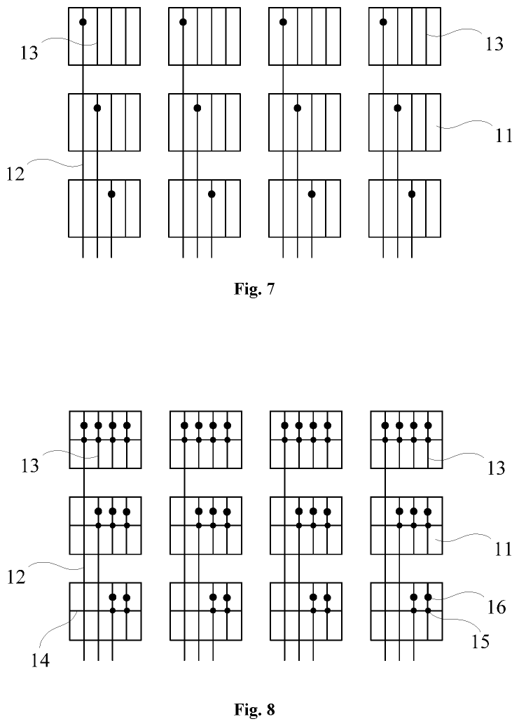

In some embodiments, in order to improve the signal intensity of the touch signals, the first conductor lines 13 shown in FIG. 7 also needs to be connected to the corresponding touch electrodes 11 and the corresponding touch signal lines 12. The connections between the first conductor lines 13 and the touch electrodes 11 may be achieved in the same manner as the connections between the touch signal lines 12 and the touch electrodes 11. For example, as described above, a second via 16 in the second insulation layer which is configured to connect a touch signal line 12 to a touch electrode 11 is disposed between the first conductor line and the touch electrode 11 so as to achieve the connection between the first conductor line 13 and the touch electrode without increasing the number of process steps. The first conductor line 13 is connected to the touch signal line 12 by the second conductor line 14 extending in the row direction. For example, as shown in FIG. 8, one second conductor line 14 extending in the row direction is disposed at the center of each touch electrode 11, and the second conductor line 14 is electrically connected, through the first vias 15, to each of the first conductor lines 13 which interact with the second conductor line 14 (i.e., each of the first conductor lines 13 connected to a touch electrode which is connected electrically to the second conductor line 14) and the touch signal line 12 which interact the second conductor line 14 (i.e., the touch signal line 12 connected to a touch electrode which is connected electrically to the second conductor line 14), so that the first conductor lines 13 can be connected to the corresponding touch signal lines 12.

In addition to being manufacturing separately inside the array substrate, the second conductor lines 14 are also formed in the same patterning process as the gate lines 101 as described above (referring to a double-gate-line design of the array substrate), or formed in the same patterning process as the touch signal lines 12 and the first conductor lines 13, and the effect of improving the signal intensity of the touch signals can be achieved.

In some embodiments, the plurality of touch signal lines 12, the plurality of first conductor lines 13 and the plurality of second conductor lines 14 are all formed in a same patterning process, reducing the number of the vias, and facilitating the improvement of the signal intensity of the touch signals.

FIGS. 2 and 8 each provide two examples of the arrangement manners of the second conductor lines 14. In FIG. 2, the number of the second conductor line(s) 14 connected to all the first conductor lines which are connected to one touch electrode 11 is two; one of the two second conductor lines 14 is located at a first edge of the region where the touch electrode 11 is located, while the other is located at a second edge of the region where the touch electrode 11 is located (the first and the second edges are the upper edge and the lower edge of a touch electrode 11 in FIG. 2, respectively). In FIG. 8, the number of the second conductor line(s) 14 connected to all the first conductor lines which are connected to one touch electrode 11 is one, and the second conductor line 14 is located at the center of the region in the row direction where the touch electrode 11 is located.

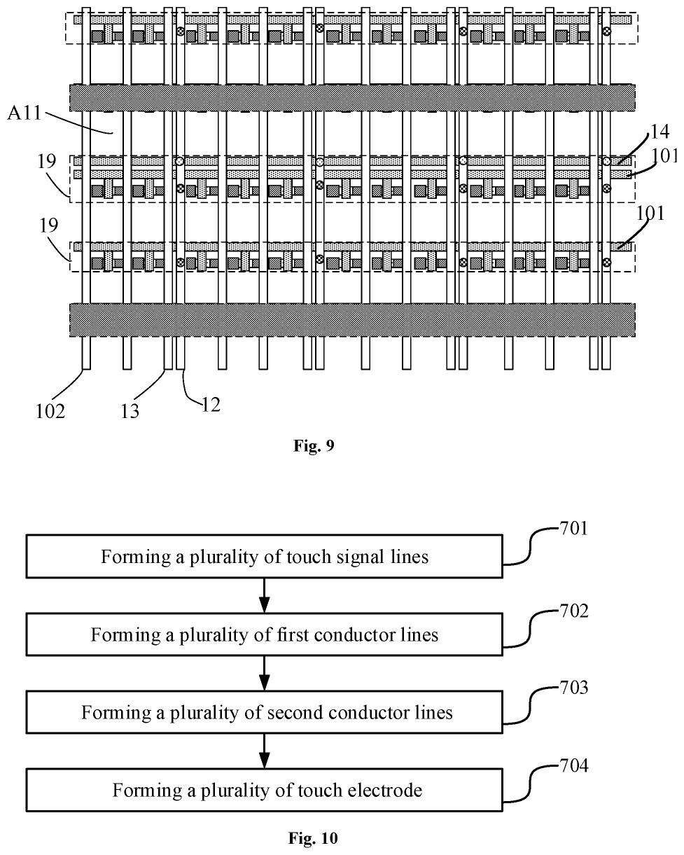

In some embodiments, referring to FIG. 9, the display area A1 includes a plurality of rows and columns of pixel aperture regions A11, each touch signal line 12 is located between two adjacent columns of pixel aperture regions A11, each first conductor line 13 is located between two adjacent columns of pixel aperture regions A11, and each second conductor line 14 is located between two adjacent columns of pixel aperture regions A11. In this way, all the touch signal lines 12, the first conductor lines 13 and the second conductor lines 14 are disposed in the region shielded by the black matrix 19, thereby reducing the influence on the display effect.

In an example, each touch signal line 12 is arranged in parallel with a data line between two adjacent columns of pixel aperture regions, and each first conductor line 13 is an invalid touch signal line separated from a touch signal line 12. The touch signal lines 12, the first conductor lines 13 and the date lines 102 are all located in a source-drain conductive layer of the array substrate. Moreover, each second conductor line 14 is arranged in parallel with a gate line 101 between two adjacent columns of pixel aperture regions. The second conductor lines 14 and the gate lines 101 are all located in the gate conductive layer of the array substrate.

In the above example, all of the first conductor lines 13 connected to one touch electrode 11 are located in the region where the touch electrode 11 is located, and a second conductor line 14 connected to all of the first conductor lines 13 which are connected to one touch electrode 11 is located in the region where the touch electrode 11 is located. In this way, it is avoided that the touch signals on adjacent touch electrodes 11 interfere with each other, further facilitating the improvement of the touch performance.

The above examples are exemplary illustration of the present disclosure. The technical solution of the present disclosure can applied to any solution in which a plurality of touch electrodes are connected to the outside of the display area by using a plurality of touch signal lines, so that the number of the contact points between the touch signal lines and the touch electrodes is increased by an arrangement related to the first and the second conductor lines, improving the signal intensity of the touch signals received by the touch electrodes, facilitating the reduction of relevant poor touch events, and improving the touch performance of the product.

FIG. 10 is a schematic flow chart of a manufacturing method of an array substrate provided by some embodiments, in which the array substrate includes the display area and the peripheral circuit area. Referring to FIG. 10, the method includes steps 701 to 702.

In step 701, forming a plurality of touch signal lines.

Wherein the plurality of touch signal lines extend in a same direction.

In step 702, forming a plurality of first conductor lines.

Wherein the plurality of first conductor lines extend in a same direction as the plurality of touch signal lines.

In step 703, forming a plurality of second conductor lines.

Wherein the plurality of second conductor lines extend in a different direction from the plurality of touch signal lines.

In step 704, forming a plurality of touch electrodes.

Wherein the plurality of touch electrodes are located in the display area, and are connected to the peripheral circuit area by the plurality of touch signal lines.

In the above method embodiment, each first conductor line is connected to the touch electrode in the thickness direction of a touch electrode; any second conductor line is connected to the touch signal line to which the touch electrode corresponding to the second conductor line is connected, and any second conductor line is connected to each first conductor line to which the touch electrode corresponding to the second conductor line is connected.

The above steps 701 to 704 are not necessarily performed strictly in the order as shown in FIG. 10. In some embodiments, the order for performing the above steps may be adaptively adjusted according to a position, in the array substrate, of a layer in which each pattern is located.

In the above method embodiment, based on the arrangement of the first and the second conductor lines, the number of the contact points between the touch signal lines and the touch electrodes is increased, and the resistances between the edges of the touch electrodes and the touch signal lines are reduced, thereby improving the signal intensity of the touch signals received by the touch electrodes, reducing poor touch events, and improving the touch performance of the product.

In an example, further referring to FIG. 2, the above manufacturing method of the array substrate includes the following process.

In a first patterning process, a pattern including a gate conductive layer is formed on a base substrate.

In an example, after cleaning and drying the surface of the base substrate (its material is such as glass, silicon wafer or organic polymer), a layer of metal material film is deposited on the surface of the base substrate by Physical Vapor Deposition (PVD) of metal materials. The parameters, such as the thickness of the film layer, and the like, are achieved by, for example, adjusting the relevant process parameters. On the basis of the parameters, the patterning process is performed on the metal material film distributed over the entire surface, which includes: coating a layer of photoresist (here, as an example, using positive photoresist) on the metal material film that has not been patterned, for example, by spin coating, irradiating the photoresist in all regions to be etched with ultraviolet light through a mask to completely expose the photoresist, then placing the entire structure in the developer to remove all the photoresist in the regions to be etched by development, etching the gate conductive layer that has not been patterned by using the remaining photoresist as a mask, and removing the remaining photoresist after the etching is completed.

The material for forming the gate conductive layer is, for example, a metal material including at least one element selected from the group consisting of iron, copper, aluminum, molybdenum, nickel, titanium, silver, zinc, tin, lead, chromium, and manganese, and the components are set according to a desired electrical conductivity. The gate conductive layer includes therein the above gate lines 101, the above a plurality of second conductor lines 14, and gate electrodes of thin film transistors in the array substrate.

In a second patterning process, a pattern including first vias is formed after the first insulation layer is formed.

In an example, the gate insulation layer (which is the first insulation layer 17) overlying the base substrate and the gate conductive layer is deposited on the base substrate and the gate conductive layer by Chemical Vapor Deposition (CVD), wherein the film thickness of the gate insulating layer satisfies the relevant requirement for the thickness of the gate insulating layer of the thin film transistor, and the setting of the parameters such as the film thickness is achieved by, for example, adjusting the relevant process parameters. On the basis of the parameters, the following process is performed: coating a layer of photoresist (here, as an example, using positive photoresist) on the first insulation layer in which the first vias 15 have not been formed, for example, by spin coating, irradiating the photoresist in all regions to be etched with ultraviolet light through a mask to completely expose the photoresist, then placing the exposed structure in the developer to remove all the photoresist in the regions to be etched by development, etching the first insulation layer in which the first vias 15 have not been formed by using the remaining photoresist as a mask to form the pattern including the first vias 15 in the first insulation layer, and removing the remaining photoresist after the etching is completed.

In the third patterning process, a pattern including the active layer is formed.

In an example, a semiconductor material layer is formed on the first insulation layer, and is patterned to form the active layer having a desired pattern.

In some embodiments, the semiconductor material for forming the active layer includes amorphous silicon, polycrystalline silicon, single crystal silicon, or a metal oxide semiconductor, and at least partial region is doped in accordance with characteristics of the thin film transistor to be implemented.

In a fourth patterning process, a pattern including the source-drain conductive layer is formed.

In an example, a source-drain conductive layer (a source conductive layer and a drain conductive layer) that has not been patterned is deposited on the first insulation layer and the active layer by Physical Vapor Deposition of metal materials. The parameters such as the thickness of the film layer and the like, are set by, for example, adjusting the relevant process parameters. On the basis of the parameters, the patterning process is performed on the source-drain conductive layer distributed over the entire surface, which includes: coating a layer of photoresist (here, as an example, using positive photoresist) on the source-drain conductive layer that has not been patterned, for example, by spin coating, irradiating the photoresist in all regions to be etched with ultraviolet light through a mask to completely expose the photoresist, then placing the exposed structure in the developer to remove all the photoresist in the regions to be etched by development, etching the source-drain conductive layer that has not been patterned by using the remaining photoresist as a mask, and removing the remaining photoresist after the etching is completed.

The material for forming the source-drain conductive layer is, for example, a metal material including at least one element selected from the group consisting of iron, copper, aluminum, molybdenum, nickel, titanium, silver, zinc, tin, lead, chromium, and manganese, and the components are set according to a desired electrical conductivity. The source-drain conductive layer includes therein the above data lines 102, the above a plurality of touch signal lines 12 and the above first conductor lines 13, and the source electrodes and drain electrodes of the thin film transistors. The connection between the second conductor lines 14 and the touch signal lines 12, and the connection between the second conductor lines 14 and the first conductor lines 13 are achieved through the first vias 15.

In a fifth patterning process, after the second insulation layer is formed, a pattern including the second vias is formed.

In an example, a second insulation layer overlying the first insulation layer and the source-drain conductive layer is deposited on the first insulation layer and the source-drain conductive layer by Chemical Vapor Deposition. On the basis of this, the following process is performed: coating a layer of photoresist (here, as an example, using positive photoresist) on the second insulation layer in which the second vias 16 have not been formed, for example, by spin coating, irradiating the photoresist in all regions to be etched with ultraviolet light through a mask to completely expose the photoresist, then placing the exposed structure in the developer to remove all the photoresist in the regions to be etched by development, etching the second insulation layer in which the second vias 16 have not been formed by using the remaining photoresist as a mask to form the pattern including the second vias 16 in the second insulation layer, and removing the remaining photoresist after the etching is completed.

In a sixth patterning process, a pattern including a first transparent conductive layer is formed.

In an example, a pattern of the first transparent conductive layer that has not been patterned is deposited on the second insulation layer by Physical Vapor Deposition of transparent conductive materials (for example, including at least one of indium tin oxide (ITO), graphene, metal mesh, conductive polymer, and nano conductive material, or a translucent conductive material such as a silver thin film), the parameters, such as the thickness of the film layer, and the like, is achieved by, for example, adjusting the relevant process parameters. On the basis of this, the patterning process is performed on the transparent conductive material distributed over the entire surface, which includes: coating a layer of photoresist (here, as an example, using positive photoresist) on the first transparent conductive layer that has not been patterned, for example, by spin coating, irradiating the photoresist in all regions to be etched with ultraviolet light through a mask to completely expose the photoresist, then placing the exposed structure in the developer to remove all the photoresist in the regions to be etched by development, etching the first transparent conductive layer that has not been patterned by using the remaining photoresist as a mask, and removing the remaining photoresist after the etching is completed. In the first transparent conductive layer, the above a plurality of touch electrodes 11 are included, and the connection between the touch electrodes 11 and the touch signal lines 11, and the connection between the touch electrodes 11 and the first conductive lines 13 have been achieved through the second vias 16.

In a seventh patterning process, after the third insulation layer is formed, a pattern including source-drain connection vias are formed.

In an example, the third insulation layer overlying the second insulation layer and the first transparent conductive layer is deposited on the second insulation layer and the first transparent conductive layer by Chemical Vapor Deposition. On the basis of this, the following process is performed: coating a layer of photoresist (here, as an example, using positive photoresist) on the third insulation layer in which the source-drain connection vias have not been formed, for example, by spin coating, irradiating the photoresist in all regions to be etched with ultraviolet light through a mask to completely expose the photoresist, then placing the exposed structure in the developer to remove all the photoresist in the regions to be etched by development, etching the second insulation layer and the third insulation layer in which the source-drain connection vias have not been formed by using the remaining photoresist as a mask to form the pattern including the source-drain connection vias in the second insulation layer and the third insulation layer, and removing the remaining photoresist after the etching is completed.

In an eighth patterning process, a pattern including a second transparent conductive layer is formed.

In an example, a pattern of the second transparent conductive layer that has not been patterned is deposited on the third insulation layer by Physical Vapor Deposition of transparent conductive materials, the settings of the parameters, such as the thickness of the film layer, and the like, is achieved by, for example, adjusting the relevant process parameters. On the basis of this, the patterning process is performed on the transparent conductive material distributed over the entire surface, which includes: coating a layer of photoresist (here, as an example, using positive photoresist) on the second transparent conductive layer that has not been patterned, for example, by spin coating, irradiating the photoresist in all regions to be etched with ultraviolet light through a mask to completely expose the photoresist, then placing the exposed structure in the developer to remove all the photoresist in the regions to be etched by development, etching the second transparent conductive layer that has not been patterned by using the remaining photoresist as a mask, and removing the remaining photoresist after the etching is completed. The second transparent conductive layer includes therein a plurality of pixel electrodes which fill in each of the pixel aperture regions, respectively, and the pixel electrodes are connected to the above source electrodes or drain electrodes through the source-drain connection vias.

When a planarization layer overlying the third insulation layer and the second transparent conductive layer is formed, the manufacturing of the array substrate is finished.

Some embodiments provide a display device which includes any of the above array substrates.

In some embodiments, the display device is any product or component having a display function, such as a display panel, a mobile phone, a tablet, a television, a display, a notebook computer, a digital photo frame, a navigator, and so on.

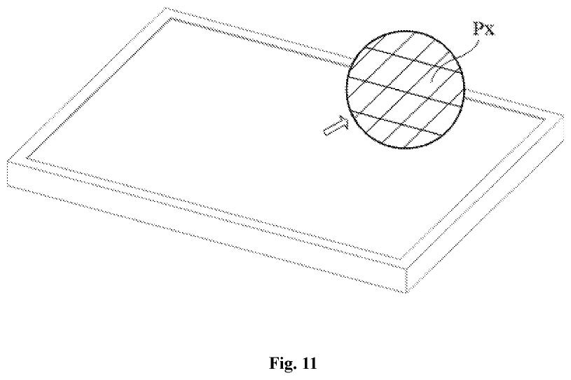

As an example, FIG. 11 is a schematic structural diagram of a display device provided by some embodiments. The display device includes any of the above display substrates. The display area of the display substrate includes therein sub-pixel regions Px arranged in rows and columns, and each sub-pixel region Px has a pixel aperture region provided therein.

Based on the arrangement of the first and the second conductor lines, the display device provided by the above embodiment increases the number of the contact points between the touch signal lines and the touch electrodes, and reduces the resistances between the edges of the touch electrodes and the touch signal lines, thereby improving the signal intensity of the touch signals received by the touch electrodes, reducing poor touch events, and improving the touch performance of the product.

1. An array substrate, comprising a display area and a peripheral circuit area, the array substrate further comprising:
a plurality of touch electrodes located in the display area;
a plurality of touch signal lines connecting the plurality of touch electrodes to the peripheral circuit area;
a plurality of first conductor lines extending in at same direction as the plurality of touch signal lines; and
a plurality of second conductor lines extending in a different direction from the plurality of touch signal lines;
wherein each touch electrode is connected to at least one first conductor line in a thickness direction of the touch electrode, and is connected to at least one touch signal line, the at least one touch signal line is connected to at least one second conductor line, and the at least one second conductor line is connected to the at least one first conductor line.

2. The array substrate according to claim 1, wherein,
each one of the touch electrodes is connected to the peripheral circuit area by the at least one ouch signal line;
the plurality of touch signal lines are formed in a same patterning process as the plurality of first conductor lines; and
the plurality of first conductor lines comprise at least one invalid touch signal line, wherein each one of the at least one invalid touch signal line is a conductor line other than the plurality of touch signal lines that is on a same straight line as any touch signal line.

3. The array substrate according to claim 1, comprising a plurality of rows of gate lines and a plurality of columns of data lines, wherein the plurality of second conductor lines are formed in a same patterning process as the plurality of rows of gate lines, and the plurality of first conductor lines, the plurality of touch signal lines and the plurality of columns of data lines are formed in a same patterning process.

4. The array substrate according to claim 3, comprising an insulation layer, wherein the plurality of rows of gate lines and the plurality of columns of data lines are located on either side of the insulation layer in a thickness direction thereof, respectively, a first via is provided in the insulation layer, and each second conductor line is connected to a corresponding first conductor line and a corresponding touch signal line through the first via.

5. The array substrate according to claim 1, comprising an insulation layer, wherein the plurality of touch signal lines and the plurality of touch electrodes are located on either side of the insulation layer in a thickness direction thereof, respectively;
a plurality of vias are provided in the insulation layer, each touch signal line is connected to a corresponding touch electrode through at least one via, each first conductor line is connected to a corresponding touch electrode through at least one via; and
the plurality of touch signal lines and the plurality of first conductor lines are formed in a same patterning process.

6. The array substrate according to claim 1, wherein the plurality of touch signal lines, the plurality of first conductor lines and the plurality of second conductor lines are formed in a same patterning process.

7. The array substrate according to claim 1, wherein the display area includes a plurality of rows and columns of pixel aperture regions, each touch signal line is located between two adjacent columns of pixel aperture regions, each first conductor line is located between two adjacent columns of pixel aperture regions, and each second conductor line is located between two adjacent rows of pixel aperture regions.

8. The array substrate according to claim 1, wherein,
all the first conductor lines connected to one touch electrode are located within a region where the touch electrode is located; and
the second conductor lines connected to the first conductor lines which are all connected to the touch electrode are located within the region where the touch electrode is located.

9. The array substrate according to claim 1, wherein,
only one second conductor line is connected to the first conductor lines which are all connected to one touch electrode, and the second conductor line is located at a center of a region where the touch electrode is located;
or,
two second conductor lines are connected to the first conductor lines which are all connected to one touch electrode, and one of the two second conductor lines is located at a first edge of the region where the touch electrode is located, and the other is located at a second edge of the region where the touch electrode is located.

10. A display device comprising the array substrate according to claim 1.

11. A manufacturing method of an array substrate, comprising:
forming a plurality of touch signal lines, wherein the plurality of touch signal lines have a same extending direction;
forming a plurality of first conductor lines, wherein the plurality of first conductor lines extend in a same direction as the plurality of touch signal lines;
forming a plurality of second conductor lines, wherein the plurality of second conductor lines extend in a different direction from the plurality of touch signal lines; and
forming a plurality of touch electrodes, wherein the array substrate comprises a display area and a peripheral circuit area, the plurality of touch electrodes are located within the display area, and the plurality of touch electrodes are connected to the peripheral circuit area through the plurality of touch signal lines;
wherein each touch electrode is connected to at least one first conductor line in a thickness direction of the touch electrode, and is connected to at least one touch signal line, the at least one touch signal line is connected to at least one second conductor line, and the at least one second conductor line is connected to the at least one first conductor line.
